(19) United States
(12) Patent Application Publication
(10) Pub. No.: US 2008/0258795 A1
(43) Pub. Date: Oct. 23, 2008

(54) LOW POWER OSCILLATOR

(75) Inventors: Franz Prexl, Niederding (DE); Hans Moormann, Hoergertshausen (DE); Wolfgang Steinhagen, Mauern (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 12/106,058

(22) Filed: Apr. 18, 2008

(30) Foreign Application Priority Data
Apr. 18, 2007 (DE) 10 2007 018 336.8

(51) Int. Cl. H03K 3/014

(52) U.S. Cl. 327/299

(57) ABSTRACT

A CMOS low frequency oscillator circuit comprising an amplifier (10) and an interface for connecting a first and a second terminal of an external crystal oscillator (14) in a feedback path of the amplifier (10). In one aspect, the oscillator circuit further comprises a regulated current source (24) supplying a regulated current to the amplifier (10) controlled by the voltage swing across the external crystal oscillator (14); and a constant current source (32) supplying a minimum constant current to the amplifier (10) independent of the voltage swing across the external crystal oscillator (14). In another aspect, the oscillator circuit further comprises an output stage (34) for converting an analog oscillator signal provided at the first and second terminals of the external crystal oscillator into a digital clock signal; wherein the output stage has a differential input (36) and a single-ended output (38) and includes a comparator (40) coupled with its differential input to the two terminals of the external crystal (14), the comparator (40) having a single-ended output; two parallel branches (42, 44) of series-connected inverters (42a, 42b, 42c, 44a, 44b, 44c), each branch having an input connected to the output of the comparator (40); a dynamic inverter (46) with complementary inputs each connected to a different output of the two parallel circuit branches (42, 44); and a plurality of series-connected output inverters (48, 50, 52).

This application claims priority from German Patent Application No. 10 2007 018 336.8, filed 18 Apr. 2007, the entirety of which is hereby incorporated herein by reference.

### FIELD OF THE INVENTION

The invention concerns a CMOS low frequency oscillator circuit comprising an amplifier and an interface for connecting a first and a second terminal of an external crystal oscillator in a feedback path of the amplifier.

### BACKGROUND

In low power applications, it is an important requirement to reduce the current consumption as much as possible. Many digital, low power applications need a clock generator. Microcontrollers, watches, AD converters and watch dogs are examples of modules that require a time reference. Often, an inexpensive 32 kHz crystal is used to provide the required frequency stability.

In order to ensure a reliable start up of the crystal, the current must not fall below a minimum value, which is contrary to the requirement of low power consumption. A known way in the state of the art is to start with a large current that is high enough to start oscillation using a separate start circuit and then to regulate the current back to a value that is just sufficient to maintain oscillation. In low frequency oscillators, e.g., 32 kHz oscillators, the current needed to maintain oscillation can become very small. This may lead to an unintentional activation of the start circuit, when a too low voltage swing is detected over the crystal. The current step due to the activation of the start circuit influences the oscillation voltage and most likely leads to clock failures. The problem of an unintentional activation of the start circuit can also occur when the external voltage across the crystal is modulated by, e.g., logic signals or other spurious frequency signals.

For use in digital applications, the analog signal provided by the crystal oscillator must be converted into a digital clock signal. Fast comparators and cross currents in logical gates or inverters used for this conversion easily contribute more to the overall current consumption than the oscillator itself.

There is a need for a CMOS low frequency oscillator circuit which reduces the overall power consumption.

### SUMMARY

In one aspect, the invention provides, a CMOS low frequency oscillator circuit which comprises a regulated current source and a constant current source. The regulated current source supplies a regulated current to an amplifier controlled by voltage swing across the external crystal oscillator; and the constant current source supplies a minimum constant current to the crystal oscillator independent of voltage swing across the external crystal oscillator. The minimum constant current supplied by the constant current source is preferably set to a value just sufficient to maintain the oscillation. In the start-up phase, the regulated current source supplies a larger amount of current so that reliable start-up is assured. In this configuration, no dedicated start circuit is needed and, because a minimum current is always provided, problems previously associated with unintentionally activated start circuits are avoided. The current value is kept in a current window with a lower and an upper limit. As the constant current source is designed to supply just the current needed to maintain the oscillation, power consumption is kept as low as possible.

In an embodiment, the amplifier is a MOS transistor and the first and second terminal of the external crystal oscillator are coupled with a drain and a gate of the MOS transistor, respectively. Preferably, the gate of the MOS transistor is AC-coupled to the external crystal oscillator. AC coupling reduces negative influences which are caused by leakage.

In an embodiment, the oscillator circuit comprises a first load capacitor connected between the first terminal of the external crystal oscillator and ground; and a second load capacitor connected between the second terminal of the external crystal oscillator and ground; the first and second load capacitors both being on-chip capacitors. No external capacitors are needed. Advantageously, the capacitances of the first and second load capacitors are programmable so that the oscillator circuit can be adapted to different frequencies, depending on the external crystal oscillator. Preferably, a regulation input of the regulated current source is AC coupled with both terminals of the external crystal oscillator. Coupling the regulated current source with both terminals reduces the ripple in the regulation loop and the voltage swing at a comparator being part of the regulated current source is doubled due to the 180-degree phase shift of the signals from both terminals. The constant current source can be of a very simple design, e.g., a transistor connected to a supply voltage.

In another aspect, the invention provides a CMOS low frequency oscillator circuit which comprises an output stage for converting an analog oscillator signal provided at the first and second terminals of the external crystal oscillator into a digital clock signal; wherein the output stage has a differential input and a single-ended output and includes a comparator connected with its differential input to the two terminals of the external crystal, the comparator having a single-ended output. The oscillator circuit further comprises two parallel branches of series-connected inverters, each branch having an input connected to the output of the comparator; a dynamic inverter with two inputs each connected to a different output of the two parallel circuit branches; and a plurality of series-connected output inverters.

Coupling the comparator, with its differential input, to the two terminals of the external crystal, means that the voltage swing at the comparator doubles due to the 180-degree phase shift of both signals. In an example embodiment, the comparator and the inverters in the two parallel circuit branches are driven by constant current, and the two outputs of the two branches output two clock signals with non-overlapping edges which are fed to the dynamic inverter. Thus, cross currents are avoided. The two parallel branches of series-connected inverters, connected to a dynamic inverter with complementary inputs, further lead to very fast rise and fall times at the input of the series-connected output inverters, which keeps the current consumption low.

Advantageously, the oscillator circuit comprises both the constant current source supplying a minimum constant current and the output stage with a differential input and a single-ended output, thus combining the power reducing effects of the different embodiments and resulting in an oscillator circuit with a very low power consumption.

### BRIEF DESCRIPTION OF THE DRAWINGS

Further advantages and features of the invention will become apparent from the following detailed description of example embodiments, considered with reference to accompanying drawings, wherein:

FIG. 1 shows a schematic diagram of an oscillator circuit in accordance with the principles of the invention; and

FIG. 2 shows, in simplified manner, clock signals output from comparator 40, and from inverters 42 a, b, c and 44 a, b, c in the embodiment of FIG. 1.

### DETAILED DESCRIPTION OF EXAMPLE EMBODIMENTS

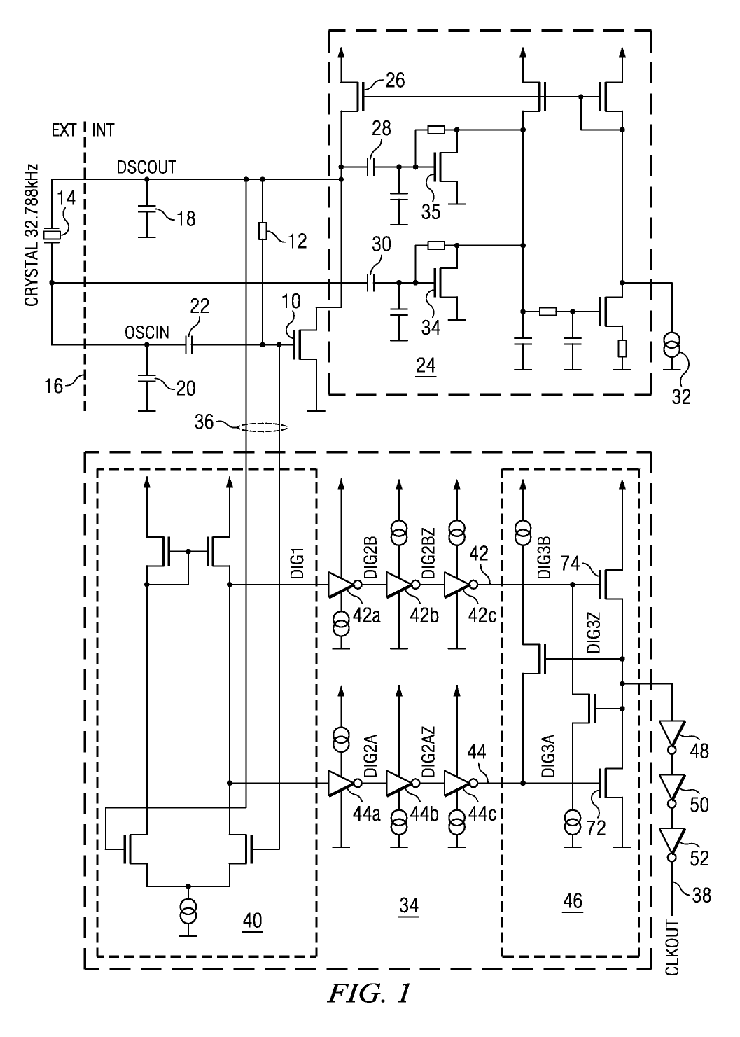

The CMOS low frequency oscillator circuit example embodiment shown in FIG. 1 comprises an amplifier in the form of a MOS transistor 10. The operating point of transistor 10 is adjusted by a resistor 12 having a high impedance. An external crystal oscillator 14 is connected in a feedback path of the amplifier, i.e., between the drain and the gate of MOS transistor 10, with its first and second terminal connected at an interface with the oscillator circuit. In a preferred embodiment, the crystal oscillator has a frequency of 32.788 kHz. A dashed line 16 shows the limit of this part of the CMOS oscillator circuit which is preferably integrated on one chip. Two load capacitors 18 and 20 are provided on the chip. Their capacitances are preferably programmable and can thus be adapted easily to another frequency of the crystal oscillator. The gate of MOS transistor 10 is AC coupled by a capacitor 22 to the second terminal of the crystal oscillator.

A regulated current source 24 comprises a current mirror transistor 26 which mirrors a current supplied by the regulated current source to MOS transistor 10. The regulated current source may be of known design. A regulation input of the regulated current source 24 is AC coupled via capacitors 28 and 30 to the two terminals of the external crystal oscillator 14. The shown oscillator circuit further comprises a constant current source 32. The constant current source 32 is independent of the regulated current source 24 and may be formed by a transistor connected to a supply voltage (not shown).

In operation, the voltage swing over the external crystal oscillator 14 is detected and input, via capacitors 28 and 30 and transistors 34 and 35, to the regulated current source as a regulation input. Dependent on the detected voltage swing, the regulated current source outputs a current to amplifier 10 via the current mirror transistor 26. The constant current source 32 feeds a constant current independently of the detected voltage swing via the regulated current source to amplifier 10. The constant current source 32 is dimensioned to supply the minimum current necessary to reliably maintain the oscillation of crystal oscillator 14. Thus, power consumption is minimized.

In a preferred embodiment, the inventive oscillator circuit further comprises an output stage 34 which transforms the analog oscillator signal into a digital clock signal. Output stage 34 comprises a differential input 36 and a single-ended output 38, as well as a comparator 40, two parallel branches 42 and 44 of series-connected inverters 42a, 42b and 42c on the first branch 42 and 44a, 44b and 44c on the second branch 44, and also a dynamic inverter 46 and three inverters 48, 50 and 52 which are series connected. The differential input 36 of the comparator 40 is connected to the two terminals of the external crystal 14, thus receiving two oscillator signals with a phase difference of 180 degrees. Therefore, the voltage swing at comparator 40 is doubled compared to the simple voltage swing. The comparator has a single-ended output which is connected to the two parallel branches 42 and 44. The inverters 42a, 42b, 42c, as well as the inverters 44a, 44b and 44c, are driven by constant current.

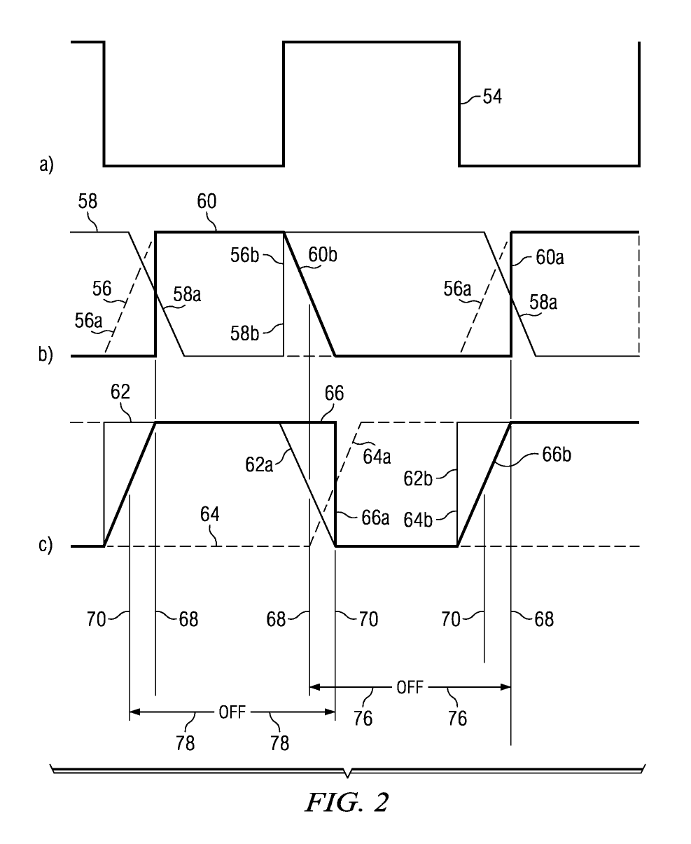

Operation of output stage 34 is explained with reference to FIG. 2. The signal shown at a) is an example of a clock signal 54 output by comparator 40; the signals shown at b) are examples of clock signals on branch 44; and the signals at c) are examples of clock signals on branch 42.

As can be seen, the small amplitude of the analog clock signal input to comparator 40 is amplified and transformed to a binary signal with a voltage level which changes between about a supply voltage and ground. The signals at b) illustrate, in a simplified manner, the clock signals on branch 44, with a dashed line 56 showing the clock signal output from inverter 44a, a thin solid line 58 showing the clock signal output from inverter 44b, and a thicker solid line 60 showing the clock signal output from inverter 44c. As the inverters are constant current driven MOS inverters, the signal edge is steep when the transistor changes from its OFF state to its ON state and the slope rate is reduced when the transistor changes from its ON state to its OFF state.

Inverter 44a is a constant current driven NMOS inverter which is ON, when clock signal 54 which is input to inverter 44a is at a high level. With clock signal 54 changing to a low level (0), i.e., to ground, the NMOS inverter 44a is turned OFF with a low slope rate as shown by edge 56a. When clock signal 54 changes to a high level (1), i.e., to a supply voltage, the NMOS inverter 44a is turned ON with a steep edge as shows edge 56b.

Clock signal 56 is input to inverter 44b which is a constant current driven PMOS inverter which is OFF, when clock signal 56 is at a high level. When clock signal 56 changes to a low level, inverter 44b is turned ON, leading to a steep edge 58b, which in FIG. 2 at b) overlies edge 56b. When clock signal 56 changes to high level, inverter 44b is turned OFF with a low slope rate at edge 58a. The switching point is assumed to be in the middle of edge 56a. Edge 58a is therefore slightly displaced compared to the corresponding edge in signal 54.

Clock signal 58 is input to inverter 44c which is a constant current driven PMOS inverter which is ON when clock signal 58 is at a low level. When clock signal 58 goes high, inverter 44c is turned OFF as shown by edge 60b having a reduced slope rate. PMOS inverter 44c is OFF, when clock signal 58 is at a high level. When clock signal 58 goes low, the output signal 60 of inverter 44c goes abruptly high with a steep edge 60a, as the PMOS inverter 44c is turned ON. Again, the switching point is supposed to be in the middle of edge 58a thus displacing edge 60a.

FIG. 2 at c) shows similarly, in a simplified manner, the clock signals on branch 42 with a thin solid line 62 showing the clock signal output from inverter 42a, a dashed line 64 showing the clock signal output from inverter 42b, and a thick solid line 66 showing the clock signal output from inverter 42c. As already explained for branch 44, the inverters are constant current driven MOS inverters, the signal edge is steep when the transistor changes from its OFF state to its ON state, and the slope rate is lower when the transistor changes from its ON state to its OFF state.

Inverter 42a is a constant current driven PMOS inverter which is ON, when clock signal 54 which is input to inverter 42a is at ground level. With clock signal 54 changing to a logic high (1), i.e., to the supply voltage, the PMOS inverter 42a is turned OFF with an edge 62a with a lower slope rate. When clock signal 54 changes to a logic low (0), i.e., to ground, the PMOS inverter 42a is turned ON with a steep edge 62b.

Clock signal 62 is input to inverter 42b which is a constant current driven NMOS inverter that is ON when clock signal 62 is at a high level. When clock signal 62 changes to a low level, inverter 42b is turned OFF, leading to an edge 64a with a lower slope rate. Edge 64a is displaced, because edge 62a has also a lower slope rate and the switching point is assumed to be in the middle of edge 62a. When clock signal 62 changes to high level, inverter 42b is turned ON with a steep edge 64b, which in FIG. 2 at c) is overlain by edge 62b.

Clock signal 64 is input to inverter 42c which is a constant current driven NMOS inverter which is OFF when clock signal 64 is at a low level. When clock signal 64 goes high, inverter 42c is turned ON as shown by a steep edge 66a. NMOS inverter 42c is ON, when clock signal 64 is at a high level. When clock signal 64 goes low, the output signal 66 of inverter 42c goes high with a lower slope rate as shown by edge 66b, as the PMOS inverter 42c is turned OFF.

The two branches, 42 and 44, are driven symmetrically by the same signal output from comparator 40. From the parallel inverters 42a and 44a, 42b and 44b, as well as 42c and 44c, only one out of a couple is ON at the same time; so, there are no cross currents in the MOS inverters 42a, 42b, 42c, 44a, 44b and 44c, as only one transistor has a current flow at any one time. With the three inverters connected in series as explained above, the signal edges are mutually shifted between the two parallel branches without the need of much current.

The outputs of the two parallel circuit branches 42 and 44 are connected to inputs of dynamic inverter 46. The switching points of clock signal 60 which is fed to an NMOS transistor 72 of dynamic inverter 46 are indicated at 68 in FIG. 2, and the switching points of clock signal 66 which is fed to a PMOS transistor 74 of dynamic inverter 46 are indicated at 70. As can be readily seen, the edges and especially the switching points do not overlap. NMOS transistor 72 is OFF when clock signal 60 is low as indicated by arrows 76, and PMOS transistor 74 is OFF when clock signal 66 is high as indicated by arrows 78. Because of the displaced edges, there is a period when both transistors 72 and 74 are OFF, but they are never ON at the same time, so there are no cross currents. The single-ended output of dynamic inverter 46 is connected to the series connected inverters 48, 50 and 52.

The output inverters reduce the output impedance to the desired line driving capability. The inventive output stage reduces cross currents and leads to fast rise and fall times, therefore keeping the power consumption low.

The illustrated embodiment shows an oscillator circuit that provides reliable oscillation, yet has low power consumption.

Those skilled in the art to which the invention relates will appreciate that many other embodiments, and variations of embodiments, are possible within the scope of the claimed invention.

What is claimed is:

1. A CMOS low frequency oscillator circuit, comprising:
an amplifier;
an interface having first and a second terminals for connecting an external crystal oscillator in a feedback path of the amplifier;
a regulated current source connected, configured and adapted for supplying a regulated current to the amplifier controlled by a voltage swing across the oscillator first and second terminals; and
a constant current source connected, configured and adapted for supplying a minimum constant current to the amplifier independent of the voltage swing.

2. The circuit of claim 1, wherein the amplifier is a MOS transistor; and wherein the oscillator first and second terminals are respectively coupled with a drain and a gate of the MOS transistor.

3. The circuit of claim 2, wherein the gate of the MOS transistor is AC coupled with one of the oscillator first and second terminals.

4. The circuit of claim 1, further comprising a first load capacitor coupled between the oscillator first terminal and ground, and a second load capacitor coupled between the oscillator second terminal and ground.

5. The circuit of claim 4, wherein the amplifier, the regulated current source, the constant current source, and the first and second load capacitors are formed on a same integrated circuit.

6. The circuit of claim 4, wherein the first and the second load capacitors comprise capacitors with programmable capacitances.

7. The circuit of claim 1, wherein a regulation input of the regulated current source is AC-coupled with each of the oscillator first and second terminals.

8. The circuit of claim, wherein the constant current source comprises a transistor connected to a bias voltage source.

9. The circuit of claim 1, wherein the amplifier is a MOS transistor;
wherein the oscillator first and second terminals are respectively coupled with a drain and a gate of the MOS transistor;
wherein the gate of the MOS transistor is AC-coupled with one of the oscillator first and second terminals; and
wherein a regulation input of the regulated current source is AC-coupled with each of the oscillator first and second terminals;
further comprising a first load capacitor coupled between the oscillator first terminal and ground, and a second load capacitor coupled between the oscillator second terminal and ground.

10. The circuit of claim 9, wherein the first and the second load capacitors comprise capacitors with programmable capacitances.

11. The circuit of claim 10, wherein the amplifier, regulated current source, constant current source, and the first and second load capacitors are formed on a same integrated circuit chip.

12. A CMOS low frequency oscillator circuit, comprising an amplifier;
an interface having first and a second terminals for connecting an external crystal oscillator in a feedback path of the amplifier;
an output stage for converting an analog oscillator signal provided at the oscillator first and second terminals into a digital clock signal; the output stage including:
a comparator having a single-ended output and a differential input with terminals respectively coupled to the oscillator first and second terminals;
two parallel branches of series-connected inverters, each branch having an input connected to the output of the comparator and having an output; and
a dynamic inverter with two inputs, each connected to an output of a different one of the two parallel circuit branches.

13. The circuit of claim 12, further comprising a plurality of series-connected output inverters.

14. The circuit of claim 12, wherein the comparator and the inverters in the two parallel circuit branches are connected, configured and adapted to be driven by a constant current.

15. The circuit of claim 12, wherein the two outputs of the two parallel circuit branches output two clock signals with non-overlapping edges.

16. The circuit of claim 12, wherein each input of the dynamic inverter receives a positive feedback from an output of the dynamic inverter.

17. The circuit of claim 12, wherein the comparator and the inverters in the two parallel circuit branches are connected, configured and adapted to be driven by a constant current; and wherein the two outputs of the two parallel circuit branches output two clock signals with non-overlapping edges.

18. The circuit of claim 17, wherein each input of the dynamic inverter receives a positive feedback from an output of the dynamic inverter.

19. A CMOS low frequency oscillator circuit, comprising:
an amplifier;
an interface having first and a second terminals for connecting an external crystal oscillator in a feedback path of the amplifier;
a regulated current source connected, configured and adapted for supplying a regulated current to the amplifier controlled by a voltage swing across the oscillator first and second terminals;
a constant current source connected, configured and adapted for supplying a minimum constant current to the amplifier independent of the voltage swing; and
an output stage for converting an analog oscillator signal provided at the oscillator first and second terminals into a digital clock signal; the output stage including:
a comparator having a single-ended output and a differential input with terminals respectively coupled to the oscillator first and second terminals;
two parallel branches of series-connected inverters, each branch having an input connected to the output of the comparator and having an output; and
a dynamic inverter with two inputs, each connected to an output of a different one of the two parallel circuit branches.

20. The circuit of claim 19, wherein the amplifier is a MOS transistor;
wherein the first and second terminals are respectively coupled with a drain and a gate of the MOS transistor;
wherein the gate of the MOS transistor is AC coupled with one of the oscillator first and second terminals;
wherein a regulation input of the regulated current source is AC-coupled with both the oscillator first and second terminals;
wherein the comparator and the inverters in the two parallel circuit branches are connected, configured and adapted to be driven by a constant current; and
wherein the two outputs of the two parallel circuit branches output two clock signals with non-overlapping edges;
further comprising a first load capacitor coupled between the first terminal and ground, and a second load capacitor coupled between the second terminal and ground.
